(19) United States
(12) Patent Application Publication
(10) Pub. No.: US 2024/0395934 A1
(43) Pub. Date: Nov. 28, 2024

(54) SEMICONDUCTOR DEVICES FOR USE IN HIGH-PRESSURE ENVIRONMENTS

(71) Applicant: The Boeing Company, Arlington, VA (US)

(72) Inventors: Leora Peltz, Pasadena, CA (US); James Satsuo Ujiie Yamaguchi, Laguna Niguel, CA (US)

(21) Appl. No.: 18/322,964

(22) Filed: May 24, 2023

(51) Int. Cl. H01L 29/78; B63G 8/00; H01L 23/29; H01L 29/10

(52) U.S. Cl. CPC H01L 29/7842; B63G 8/001; H01L 23/291; H01L 23/293; H01L 29/1033; H01L 29/7851; B63G 2008/002

(57) ABSTRACT

The present disclosure provides examples of semiconductor devices for operation in different pressure environments, such as high-pressure environments. In one example, a semiconductor device for operation in a high-pressure environment is provided. The semiconductor device comprises a plurality of channels controlled by at least one gate, the plurality of channels comprising a first channel and a second channel, wherein the first channel comprises a first stress layer configured for operation in a first pressure environment, and the second channel comprises a second stress layer different from the first stress layer, the second stress layer configured for operation in a second pressure environment of a different pressure than the first pressure environment.

### FIELD

The field of invention relates generally to semiconductor devices, and more specifically, semiconductor devices fabricated for use in different pressure environments.

### BACKGROUND

Semiconductor devices are devices that rely on the properties of semiconductor materials for the passage and control of electric currents. Widely used in the manufacturing of electronics due to their reliability, compactness, and low cost, these devices often include large numbers of transistors and other electronic components that, together, operate to perform various functions. These devices can be manufactured as integrated circuits that include elements for performing multiple tasks on a single chip device.

Semiconductor devices, such as processors, memory, application-specific integrated circuits (ASICs), and system-on-chip (SoC) devices, can perform differently depending on external environmental influences. For example, in deep undersea environments, pressure and sea water become considerations that affect the design and deployment of electronic devices used in such applications. Pressure at such depths (e.g., 10 megapascals (MPa) at 1,000 meters (m), 100 MPa at 10,000 m, etc.) can stress semiconductor devices, causing semiconductor lattice deformations that can change the electrical properties of such devices. At a high enough pressure, dies in the devices can catastrophically fail due to cracks. Similar issues can arise in other high-pressure environments, such as during or in furtherance of space exploration.

For undersea applications, high ambient pressure can limit the use of certain undersea vehicles to shallow depths where the pressure exerted by the water column is lower. Vehicles operating at deeper depths typically implement rugged enclosures for containing electronics. The enclosures can serve as pressure chambers that maintain internal pressure to provide adequate protection for electronic devices from the undersea environment. Examples of such electronic devices can include sensitive and/or critical electronics (e.g., onboard computers, power source, drivers). The use of rugged enclosures presents several issues. Fabricating such enclosures with materials capable of withstanding the high-pressure environments found in the deeper undersea depths can be costly. Additionally, the volume and weight of such enclosures can occupy valuable payload space and reduce propulsion efficiency of the vehicle, respectively. For example, enclosures protecting electronics from high ambient pressures found in deep undersea environments are typically constructed with thick steel walls in bulky dimensions (e.g., 25″-30″ dimensions; 100 lbs-120 lbs weight). Oftentimes, multiple pressure enclosures (e.g., 9-12) are implemented per undersea vehicle. This large footprint and weight can complicate the operations of such undersea vehicles.

### SUMMARY

The present disclosure provides examples of semiconductor devices for operation in pressure environments that can impact semiconductor device performance. In one example, a semiconductor device for operation in a high-pressure environment is provided. The semiconductor device comprises a plurality of channels controlled by at least one gate, the plurality of channels comprising a first channel and a second channel, wherein the first channel comprises a first stress layer configured for operation in a first pressure environment, and the second channel comprises a second stress layer different from the first stress layer, the second stress layer configured for operation in a second pressure environment of a different pressure than the first pressure environment.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 schematically illustrates an example vehicle with a semiconductor device operating undersea.

FIG. 2A schematically illustrates another example vehicle with a semiconductor device operating undersea.

FIG. 2B shows a cross-sectional view of the semiconductor device and a circuit board of FIG. 2A.

FIG. 3 schematically illustrates an example planar field-effect transistor configured for operation in different pressure environments.

FIG. 4A shows a cross-sectional view of an example fin field-effect transistor configured for operation in different pressure environments.

FIG. 4B shows a top view of an example fin field-effect transistor configured for operation in different pressure environments.

FIG. 5 is a flow chart showing an example method for operating a semiconductor device in different pressure environments.

### DETAILED DESCRIPTION

Examples of semiconductor devices incorporating stress layers that are configured for use in different pressure environments are disclosed. Semiconductor devices can be custom fabricated for operation in different environments, including high-pressure environments such as those found in deep undersea depths. For example, a stress resilient-by-design-process for implementing such devices can include configuring the fabrication process at the die and/or board level to counteract stress effects caused by high-pressure environments. Such customizations can beneficially enable operation of semiconductor devices in high-pressure environments without the use of rugged enclosures. A high-pressure environment can include any environment with sufficiently high ambient pressures to impact semiconductor device performance.

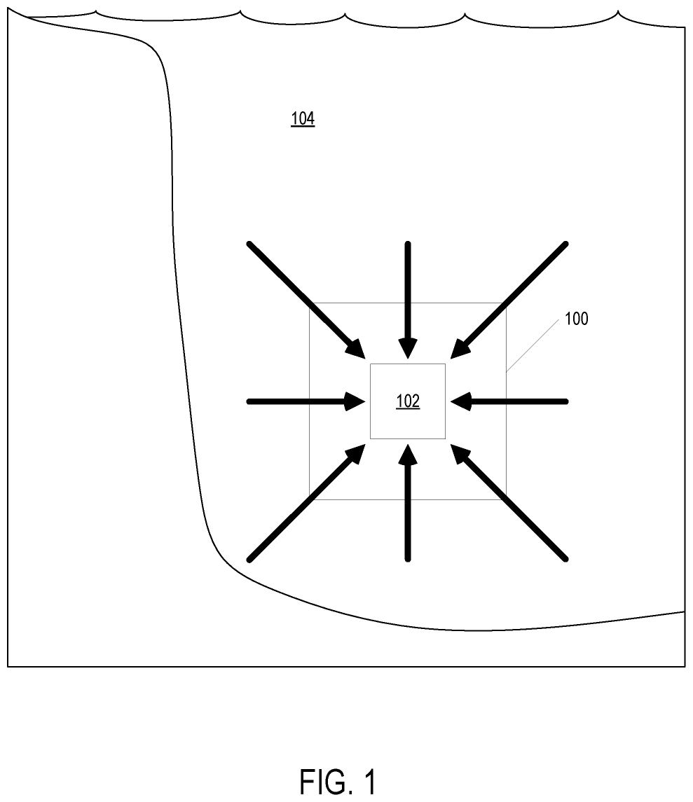

FIG. 1 schematically illustrates an example vehicle 100 with a semiconductor device 102 operating undersea 104. Operation of semiconductor devices and electronics in an undersea environment presents different considerations compared to surface applications. The ambient pressure can become significant at certain depths (e.g., 1000 m or greater), affecting the operation of such devices on a microscopic scale. As mentioned above, current solutions for isolating these devices from the ambient pressure and sea water include the use of rugged enclosures, which can be cost- and/or space-prohibitive. By fabricating and implementing semiconductor devices that are stress-resilient, such enclosures become unnecessary, allowing for more mission payload space and further vehicle miniaturization designs. For example, the semiconductor device 102 in the depicted example is designed to operate in undersea environments without the need of a pressure-reducing enclosure for maintaining internal pressure. The device is instead fabricated to withstand the ambient pressure in such environments, mitigating the effects that ambient pressure may have on its performance through its internal construction.

In some implementations, the semiconductor device 102 is configured to operate faster at a depth below sea level compared to standard atmospheric pressure. The semiconductor device 102 can also be configured for operation at multiple different pressure environments. Techniques for the implementation of stress-resilient devices include but are not limited to the use of stress layers, microcapsules, micropores, and coating layers, which can be implemented in non-uniform geometries. In some implementations, a non-uniform geometry implementation is configured to create non-uniform stresses that vary with ambient pressure. Such implementations can enable the device to compensate for the different ambient pressures at various depths. The different layers and encapsulants described above can be implemented in various ways. Layers can be applied on the outside of the device and/or internally. For example, layers can be embedded in the gate area. In some implementations, the device includes local implantation of stress-compensating volume near the gate area. Different types of materials can be used for the layers and encapsulants, the choice of which can depend on the implementation.

A stress layer is a layer of material that has a lattice constant different from a neighboring silicon (Si) (or other semiconductor) layer used in the device. As an example, a stress layer can comprise a layer of silicon-germanium (SiGe) to stress a neighboring silicon layer. The different lattice constants of the silicon layer and the silicon-germanium layer cause strain in the silicon lattice. The strain can provide better electron mobility through the silicon. Current stress layers are used to improve semiconductor device speeds at pressures found on the surface of the earth (e.g. approximately one atmosphere of air pressure). However, semiconductor devices with such stress layers can suffer performance degradation at pressures found in a deep sea environment, for example. Thus, a semiconductor device intended for deep sea use can have one or more stress layers that are configured to optimize device use at high pressures, rather than at comparatively lower pressures found on the earth's surface. Further, as described below, a semiconductor device can have different field-effect transistor (FET) channels configured for use at different pressures. This can provide for optimized performance across a range of different pressures, from the surface of the Earth to deep sea.

A microcapsule is a protective layer that surrounds the semiconductor device. A microcapsule can be formed, for example, around a semiconductor device package. The microcapsule can provide protection against physical damage in high-pressure environments. For example, a microcapsule can include a compressive material to distribute and absorb compressive forces. The term “microcapsule” refers to the smaller scale of the encapsulating structure compared to traditional protective/enclosure structures, such as those made of steel. A microcapsule can be formed around a semiconductor package by techniques such as additive manufacturing, sputtering, chemical or physical vapor deposition, etching, or any other suitable technique known to those of ordinary skill in the art without undue experimentation. Alternatively, or additionally, to a microcapsule, in some examples a coating layer can be deposited over the semiconductor device, such as by coating all or a portion of a circuit board comprising the packaged semiconductor device, to provide various protective measures. For example, the coating layer can be configured to protect the semiconductor device from the effects of prolonged indirect exposure to the undersea environment. Examples of microcapsule and coating layer materials can include various types of ceramics, such as silicon carbide and silicon nitride. In some implementations, the microcapsule and/or coating layer comprises an organic-based material, such as corrosion-resistant polymers.

Different techniques or combinations of techniques can be used to configure a semiconductor device for operation in different environments, depending on the pressures and other environmental conditions of the target environment in which the semiconductor device is designed to operate. For example, any one or more of a stress layer, a microcapsule, or a coating layer can be used to configure a semiconductor device for operation at high pressures.

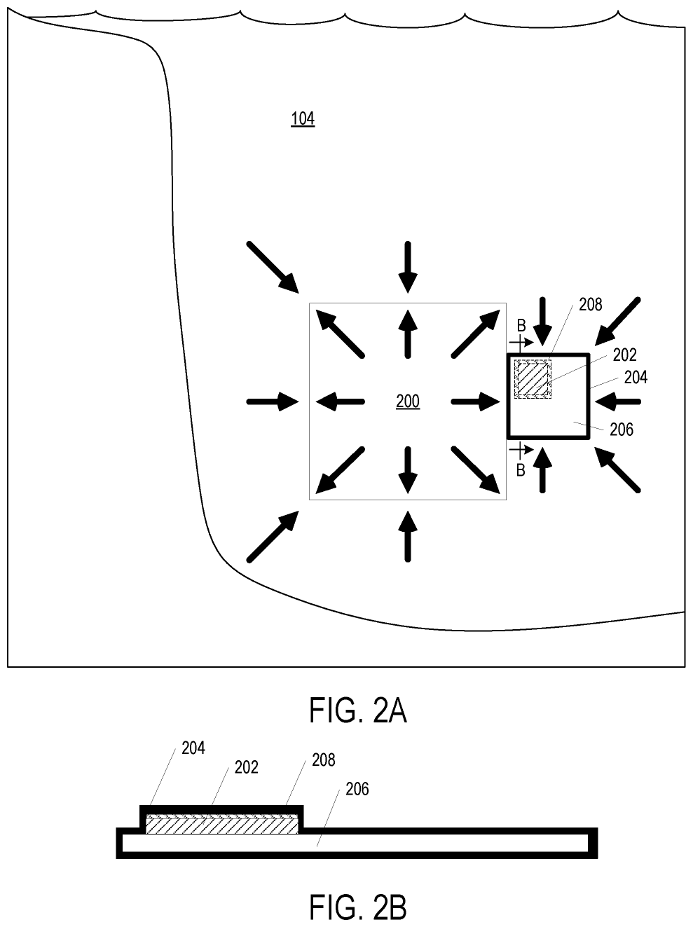

In the example of FIG. 1, vehicle 100 is an unmanned vehicle, and the compartment containing the semiconductor device 102 is not pressurized. As such, the semiconductor device 102 is affected by the ambient pressure from the surrounding sea water. Other configurations can also be implemented. For example, a manned and/or pressurized vehicle also can contain a semiconductor device according to the present disclosure. FIG. 2A schematically illustrates another example vehicle 200 with a semiconductor device 202 operating undersea 104. FIG. 2B schematically shows a cross-sectional view taken along line B-B of FIG. 2A. The semiconductor device 202 is mounted to a circuit board 206 and is disposed on the vehicle 200 such that it is exposed to undersea conditions. Example conditions include direct or indirect exposure to elevated pressures and direct exposure to potentially corrosive conditions. For example, the sea water contains salt ions (which are electrically conductive, and change the resistance between terminals of the device, or cause short circuits of the device). Moreover, sea water can carry corrosive ions that can potentially erode or otherwise harm the semiconductor device 202. Thus, the semiconductor device 202 can be configured to withstand direct prolonged exposure to corrosion arising from sea water. For example, the semiconductor device 202 can include a microcapsule 204 surrounding a package of the semiconductor device 202 to protect the semiconductor device 202 from corrosions. Additionally or alternatively, a coating 208 can cover the circuit board 206 and the semiconductor device 202. In some examples, a compressible material can be used for the microcapsule 204 and/or the coating 208. Further, in some examples, the circuit board 206 comprising the semiconductor device 202 can be located within another container (not shown), such as a pouch-like vessel. The pouch can be designed with a material that can provide at least some protection from seawater contacting the semiconductor device 202. In some implementations, the pouch is made of a deformable (e.g. compressible) material to prevent warping of the semiconductor device 202 by distributing and absorbing forces from the ambient pressure of the deep undersea.

Although FIG. 1 and FIG. 2 schematically illustrate vehicles for use in undersea environments, other types of vehicles can also make use of semiconductor devices configured for operation in different pressure environments. The customized semiconductor devices can be implemented for any application where pressure affects the performance of non-customized semiconductor devices. For example, as mentioned above, manned undersea vehicles can also make use of semiconductor devices configured for operation in different pressure environments. In such cases, the manned undersea vehicle may include a pressurized compartment, such as a crew compartment, and an unpressurized compartment. In an unpressurized environment, semiconductor devices configured for operation in different pressure environments can be advantageously implemented. Another example of applications in which semiconductor devices configured for operation in different pressure environments can be advantageously implemented includes space vehicles used in exploration of environments with high ambient pressures and/or exposure to external chemical effects.

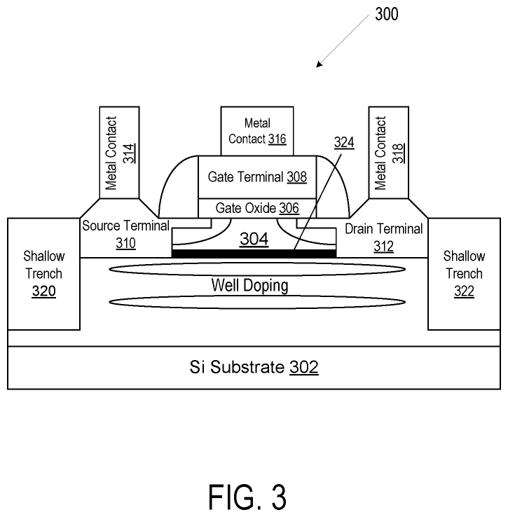

Stress-resilient designs can be applied to various semiconductor structures and technologies. FIG. 3 schematically illustrates an example planar field-effect transistor (FET) 300 configured for operation in different pressure environments than on the surface of the Earth. FET 300 can represent a metal oxide semiconductor FET (MOSFET) in some examples. In other examples, a device can comprise a logic structure not formed using silicon, such as, a carbon nanotube transistor (CNTFET) or a nanowire transistor. The FET 300 is formed on a silicon (or other semiconductor) substrate 302. A layer of doped silicon 304 is formed on the substrate 302 to form a channel for the FET. A gate oxide layer 306 is formed over the doped silicon 304. A gate terminal 306 formed from a suitable conductor (e.g., polycrystalline silicon, aluminum, tungsten, titanium, gold, or other suitable materials and alloys thereof) is used to control an electric field within the doped silicon 304. The FET further includes metal contacts 314, 316, 318 respectively for the source terminal 310, the gate terminal 308, and the drain terminal 312. Shallow trench isolation regions 320, 322 are formed on either side of the source terminal 310 and the drain terminal 312 in this example to electrically isolate FET 300 from adjacent devices on substrate 302.

The FET 300 further includes at least one stress layer 324. The stress layer 324 can be configured to strain the silicon in the neighboring areas, enabling devices to operate at higher speeds compared to unstrained silicon in a selected pressure environment. This can be particularly useful for high-speed electronic devices. Strained silicon is a region of silicon in which the lattice experiences tensile or compressive stress due to interactions of the silicon lattice with the lattice of the stress layer 324. The stress layer 324 enables the FET 300 to be stress resilient, as the strained silicon can be formed in anticipation of a high-pressure environment, which compresses the silicon. Pre-strained silicon would allow the device to compensate for the compressive effects of ambient pressure at deep sea, for example. Silicon that is relatively more strained can compensate for relatively higher ambient pressures.

The stress layer 324 can be made of any suitable material. For example, a layer of silicon-germanium (SiGe) can be formed at a suitable location to configure electron flow through the channel within doped silicon 304 to be faster within a target pressure regime compared to a channel within unstrained silicon. Since the lattice constant of the silicon-germanium layer is larger than the lattice constant of silicon due to the larger radii of the germanium atoms, the silicon lattice is under tensile stress, forming strained silicon. The stretched silicon atoms reduce the atomic forces that interfere with the movement of electrons through the silicon, resulting in faster device operation compared to a channel within unstrained silicon.

The depicted stress layer 324 is disposed below the channel within doped silicon 304, in the perspective of FIG. 3. The strained silicon can enable faster electron movement compared to a channel within unstrained silicon, and thus can result in faster operation in a target pressure environment. In some implementations, more than one stress layer 324 can be used. As an example, additional stress layers can be formed in trenches that run lengthwise at least partially along the channel between source terminal 310 and drain terminal 312.

Stress layer 324, plus one or more additional stress layers in some examples, can be utilized to fabricate a semiconductor device capable of operating in multiple pressure environments. For example, a semiconductor device can include FETs with different channels configured for higher electron mobility in different pressure environments. As a more specific example, a first stress layer can cause a first level of strain in or adjacent to a first FET channel for operation in a first pressure environment, and a second stress layer can cause a second level of strain in or adjacent to a second FET channel for operation in a second pressure environment different than the first pressure environment. The first stress layer can include a first silicon-containing composition with a first lattice constant, and the second stress layer can include a second, different silicon-containing composition with a second lattice constant different from the first lattice constant. The first and second stress layers can be used in different FET channels that are controlled by a same gate signal in some examples. Different amounts of strain result in a different amount of compensation for ambient pressure. As such, the two channels are configured operation in two different pressure environments. This principle can be extended to more than two stress layers, as would be understood by those of ordinary skill in the art without undue experimentation. As a more specific example, the first stress layer can include a first SiGe composition with a first Si/Ge molar ratio, and the second stress layer can include a second SiGe composition with a second Si/Ge molar ratio that is different from the first Si/Ge molar ratio.

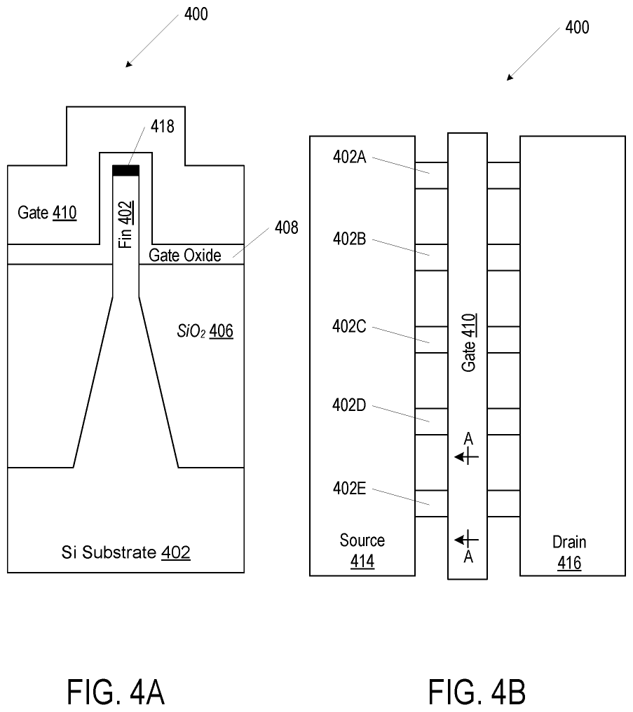

Other semiconductor device structures can be similarly configured for use in different pressure environments. FIGS. 4A and 4B schematically illustrate an example fin field-effect transistor (FinFET) configured for operation in different pressure environments. FinFETs are a class of devices with channels formed in three-dimensional fins that are partially surrounded by gates. FinFET architectures can allow for higher transistor densities than planar FET architectures.

FIG. 4A shows a cross-sectional view of a fin 402 of the FinFET 400. The FinFET 400 includes a silicon substrate 404 upon which the fin 402 is formed. A layer of silicon oxide 406 supports the fin 402. The FinFET 400 further includes a gate oxide layer 408 that wraps partially around the fin 402, electrically insulating it from the gate 410. FIG. 4B shows a top view of the FinFET 400, depicting several fins 402A-402E. Line A-A shows the cross-sectional plane of FIG. 4A. The channels formed by the multiple fins 402A-402E are electrically connected to a common source 414 and drain 416, all controlled by the gate 410.

The FinFET 400 includes a stress layer 418. The stress layer 418 can be formed using standard semiconductor fabrication processes, including patterning, deposition and etching processes. Further, the stress layer can include any suitable composition, including but not limited to silicon-containing compositions such as silicon germanium. The depicted stress layer 418 is disposed at a top of a fin 402, wherein the fin 402 forms a channel defining a conductive path between the source terminal 414 and the drain terminal 416. In other examples, a stress layer can have any other suitable location. For example, the layer can be disposed below the gate, at portions of the gate, around the gate, etc. One or more additional stress layers can be utilized to enable operation in multiple pressure environments. For example, the FinFET 400 can further include a second stress layer configured for operation in a second pressure environment different from the first pressure environment in which the first stress layer was configured to operate.

Different stress layers for different channels can include silicon-containing compositions with different lattice constants, forming different channels with silicon that is strained differently. For example, different stress layers can be implemented for at least two fins 402 in the FinFET 400. In further implementations, a different stress layer is implemented for each fin 402A-402E in the FinFET 400. In such an example, each fin 402A-402E defines a channel configured for optimal performance at a different pressure than each other fin. While the fins 402A-402E of FIG. 4B are connected to a common source 414 and a common drain 416 and are controlled by a common gate 410, in other examples, each fin 402A-402E configured for a different pressure can be connected to a separate source and a separate drain and be controlled by a different gate. In such examples, pressure sensor data can be used to determine which source/drain/gate to use for computations.

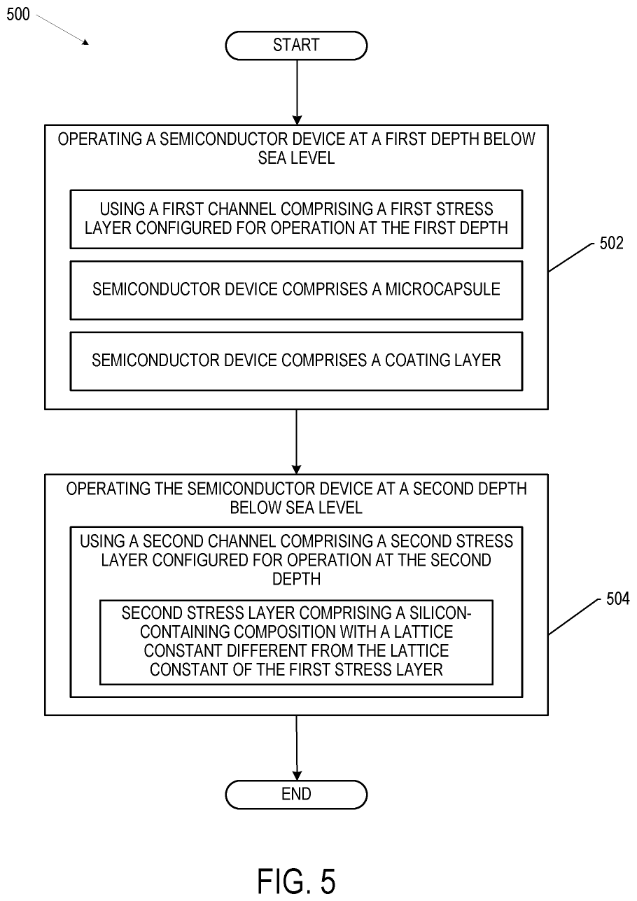

FIG. 5 is a flow chart showing an example method 500 for operating a semiconductor device in different pressure environments. At step 502, the method 500 includes operating a semiconductor device at a first depth below sea level. At the first depth, the semiconductor device operates using a first channel, where the first channel includes a first stress layer configured for operation at the first depth. For example, the first stress layer can include a material composition that forms silicon strained such that the first channel has better electron mobility than a second channel under the effects of pressure at the first depth. The first stress layer can be made of various material compositions. In some implementations, the first stress layer includes a silicon-containing composition. In further implementations, the first stress layer includes a layer of silicon germanium.

In some implementations, the semiconductor device includes a microcapsule. The microcapsule can be formed by building/depositing a material around a semiconductor device to form an encapsulant. In some implementations, the semiconductor device includes a coating layer. The coating layer can also be used in combination with the microcapsule. Examples of microcapsule and coating layer materials may include various types of ceramics, such as silicon carbide, silicon nitride, and aluminum nitride. In some implementations, the microcapsule and/or coating layer comprises an organic-based material, such as a suitable polymer.

At step 504, the method 500 includes operating the semiconductor device at a second depth below sea level. At the second depth, the aforementioned second channel, with a second stress layer that is configured for a second depth, has better electron mobility than the first channel at the second depth. For example, the second stress layer can include a material composition that forms silicon strained such that the second channel is still operational under the effects of pressure at the second depth. In such cases, the material composition of the second stress layer includes a lattice constant that is different from the lattice constant of the material composition of the first stress layer.

The first and second channels can be electrically connected to one or more pairs of source and drain terminals. In some implementations, the first and second channels are electrically connected to the same source terminal and drain terminal. In other implementations, the first channel is connected to a first source and a first drain, and the second channel is connected to a second source and a second drain. The first and second channels can be controlled by at least one gate. For example, in some implementations, the first channel is controlled by a first gate, and the second channel is controlled by a second gate. In other implementations, the first and second channels are controlled by the same gate. Semiconductor devices can be implemented in various ways. In some implementations, the semiconductor device is a planar MOSFET. In some implementations, the semiconductor device is a FinFET.

In some implementations, the method 500 includes operating the semiconductor device at a third depth below sea level using a third channel. The third channel can include a third stress layer configured for operation at the third depth, different from the first stress layer and the second stress layer.

Further, the disclosure comprises configurations according to the following clauses.

Clause 1. A semiconductor device for operation in different pressure environments, the semiconductor device comprising: a plurality of channels controlled by at least one gate, the plurality of channels comprising a first channel and a second channel, wherein: the first channel comprises a first stress layer configured for operation in a first pressure environment, and the second channel comprises a second stress layer different from the first stress layer, the second stress layer configured for operation in a second pressure environment of a different pressure than the first pressure environment.

Clause 2. The semiconductor device of clause 1, wherein the plurality of channels further comprises a third channel comprising a third stress layer different from the first stress layer and the second stress layer.

Clause 3. The semiconductor device of clause 1 or clause 2, wherein the semiconductor device is a fin field-effect transistor.

Clause 4. The semiconductor device of clauses 1 to 3, wherein the first stress layer comprises a first silicon-containing composition with a first lattice constant, and wherein the second stress layer comprises a second silicon-containing composition with a second lattice constant that is different than the first lattice constant.

Clause 5. The semiconductor device of clauses 1 to 3, wherein the first channel and the second channel are electrically connected to a first source and a first drain.

Clause 6. The semiconductor device of clause 5, wherein the at least one gate comprises a gate configured to the control the first channel and the second channel.

Clause 7. The semiconductor device of clauses 1 to 3, further comprising a microcapsule encapsulating the semiconductor device.

Clause 8. The semiconductor device of clause 7, wherein the microcapsule comprises one or more of a ceramic or a polymer.

Clause 9. The semiconductor device of clauses 1 to 8, further comprising a coating layer.

Clause 10. A vehicle for operation in different pressure environments, the vehicle comprising: a semiconductor device comprising: a plurality of channels controlled by at least one gate, the plurality of channels comprising a first channel and a second channel, wherein: the first channel comprises a first stress layer configured for operation in a first pressure environment; and the second channel comprises a second stress layer different from the first stress layer, the second stress layer configured for operation in a second pressure environment of a different pressure than the first pressure environment.

Clause 11. The vehicle of clause 10, wherein the first stress layer comprises a first silicon-containing composition with a first lattice constant, and wherein the second stress layer comprises a second silicon-containing composition with a second lattice constant that is different than the first lattice constant.

Clause 12. The vehicle of clause 10 or clause 11, wherein the first channel and the second channel are electrically connected to a first source and a first drain.

Clause 13. The vehicle of clauses 10 to 12, further comprising a non-pressurized compartment in which the semiconductor device is disposed.

Clause 14. The vehicle of clauses 10 to 13, wherein the semiconductor device is disposed on an external surface of the vehicle.

Clause 15. The vehicle of clauses 10 to 14, wherein the vehicle is an undersea unmanned vehicle.

Clause 16. A method of operating a semiconductor device, the method comprising: operating a semiconductor device at a first depth below sea level using a first channel of the semiconductor device, wherein the first channel comprises a first stress layer configured for operation at the first depth; and operating the semiconductor device at a second depth below sea level using a second channel of the semiconductor device, wherein the second channel comprises a second stress layer configured for operation at the second depth.

Clause 17. The method of clause 16, wherein the first stress layer comprises a first silicon-containing composition with a first lattice constant, and wherein the second stress layer comprises a second silicon-containing composition with a second lattice constant that is different than the first lattice constant.

Clause 18. The method of clause 16 or clause 17, wherein the first channel and the second channel are electrically connected to a first source and a first drain.

Clause 19. The method of clauses 16 to 18, wherein the semiconductor device further comprises a microcapsule.

Clause 20. The method of clauses 16 to 19, wherein the semiconductor device further comprises a coating layer.

1. A semiconductor device for operation in different pressure environments, the semiconductor device comprising:
a plurality of channels controlled by at least one gate, the plurality of channels comprising a first channel and a second channel, wherein:
the first channel comprises a first stress layer configured for operation in a first pressure environment, and
the second channel comprises a second stress layer different from the first stress layer, the second stress layer configured for operation in a second pressure environment of a different pressure than the first pressure environment.

2. The semiconductor device of claim 1, wherein the plurality of channels further comprises a third channel comprising a third stress layer different from the first stress layer and the second stress layer.

3. The semiconductor device of claim 1, wherein the semiconductor device is a fin field-effect transistor.

4. The semiconductor device of claim 1, wherein the first stress layer comprises a first silicon-containing composition with a first lattice constant, and wherein the second stress layer comprises a second silicon-containing composition with a second lattice constant that is different than the first lattice constant.

5. The semiconductor device of claim 1, wherein the first channel and the second channel are electrically connected to a first source and a first drain.

6. The semiconductor device of claim 5, wherein the at least one gate comprises a gate configured to the control the first channel and the second channel.

7. The semiconductor device of claim 1, further comprising a microcapsule encapsulating the semiconductor device.

8. The semiconductor device of claim 7, wherein the microcapsule comprises one or more of a ceramic or a polymer.

9. The semiconductor device of claim 1, further comprising a coating layer.

10. A vehicle for operation in different pressure environments, the vehicle comprising:
a semiconductor device comprising:
a plurality of channels controlled by at least one gate, the plurality of channels comprising a first channel and a second channel, wherein:
the first channel comprises a first stress layer configured for operation in a first pressure environment; and
the second channel comprises a second stress layer different from the first stress layer, the second stress layer configured for operation in a second pressure environment of a different pressure than the first pressure environment.

11. The vehicle of claim 10, wherein the first stress layer comprises a first silicon-containing composition with a first lattice constant, and wherein the second stress layer comprises a second silicon-containing composition with a second lattice constant that is different than the first lattice constant.

12. The vehicle of claim 10, wherein the first channel and the second channel are electrically connected to a first source and a first drain.

13. The vehicle of claim 10, further comprising a non-pressurized compartment in which the semiconductor device is disposed.

14. The vehicle of claim 10, wherein the semiconductor device is disposed on an external surface of the vehicle.

15. The vehicle of claim 10, wherein the vehicle is an undersea unmanned vehicle.

16. A method of operating a semiconductor device, the method comprising:
operating a semiconductor device at a first depth below sea level using a first channel of the semiconductor device, wherein the first channel comprises a first stress layer configured for operation at the first depth; and
operating the semiconductor device at a second depth below sea level using a second channel of the semiconductor device, wherein the second channel comprises a second stress layer configured for operation at the second depth.

17. The method of claim 16, wherein the first stress layer comprises a first silicon-containing composition with a first lattice constant, and wherein the second stress layer comprises a second silicon-containing composition with a second lattice constant that is different than the first lattice constant.

18. The method of claim 16, wherein the first channel and the second channel are electrically connected to a first source and a first drain.

19. The method of claim 16, wherein the semiconductor device further comprises a microcapsule.

20. The method of claim 16, wherein the semiconductor device further comprises a coating layer.
